(19) United States
(12) Patent Application Publication
(10) Pub. No.: US 2012/0168968 A1
(43) Pub. Date: Jul. 5, 2012

(54) EPOXY RESIN COMPOSITION FOR ENCAPSULATING A SEMICONDUCTOR DEVICE, METHOD OF ENCAPSULATING A SEMICONDUCTOR DEVICE, AND SEMICONDUCTOR DEVICE

(76) Inventors: Young Kyun Lee, Uiwang-si (KR); Eun Jung Lee, Uiwang-si (KR); Kyoung Chul Bae, Uiwang-si (KR)

(21) Appl. No.: 13/337,410

(22) Filed: Dec. 27, 2011

(30) Foreign Application Priority Data
Dec. 29, 2010 (KR) 10-2010-0138323

(51) Int. Cl. H01L 23/29; H01L 21/56; C08K 3/36; C08L 63/02; C08K 3/22

(52) U.S. Cl. 257/788; 523/457; 523/440; 438/123; 257/E23.119; 257/E21.502

(57) ABSTRACT

An epoxy resin composition for encapsulating a semiconductor device, a method of encapsulating a semiconductor device, and a semiconductor device, the composition including an epoxy resin; a curing agent; a curing accelerator; an inorganic filler; and a flame retardant; wherein the flame retardant includes boehmite, and is present in an amount of about 0.1 to 20% by weight (wt %), based on a total weight of the epoxy resin composition.

### BACKGROUND

1. Field

Embodiments relate to an epoxy resin composition for encapsulating a semiconductor device, a method of encapsulating a semiconductor device, and a semiconductor device.

2. Description of the Related Art

In an epoxy resin composition for encapsulation of a semiconductor device, a UL94 flammability of V0 is desirable. Flammability may be determined based upon the UL94 standard of Underwriters Laboratories. UL94 testing may be performed in accordance with ASTM D635; and a specimen may be given a V grade based on performance of burning cotton, burning time, glow time, combustion extent, or the like.

### SUMMARY

Embodiments are directed to an epoxy resin composition for encapsulating a semiconductor device, a method of encapsulating a semiconductor device, and a semiconductor device.

The embodiments may be realized by providing an epoxy resin composition for encapsulating a semiconductor device, the composition including an epoxy resin; a curing agent; a curing accelerator; an inorganic filler; and a flame retardant, wherein the flame retardant includes boehmite, and is present in an amount of about 0.1 to 20% by weight (wt %), based on a total weight of the epoxy resin composition.

The boehmite may have an average particle diameter of about 0.1 to about 10 μm.

The boehmite may have an average particle diameter of about 1 to about 7 μm.

The inorganic filler may include silica.

A weight ratio of the boehmite to the silica may be about 1:3 to about 1:900.

The epoxy resin composition may include about 2 to about 15 wt % of the epoxy resin, about 0.5 to about 12 wt % of the curing agent, about 0.01 to about 2 wt % of the curing accelerator, about 70 to about 95 wt % of the inorganic filler, and about 0.1 to about 20 wt % of the boehmite.

The epoxy resin composition may further include about 0.01 to about 5 wt % of a silane coupling agent.

The coupling agent may include at least one of epoxy silane, aminosilane, ureido silane, and mercapto silane.

The epoxy resin may include about 10 to about 90 wt % of an epoxy resin represented by Formula 2, below, based on a total amount of the epoxy resin,

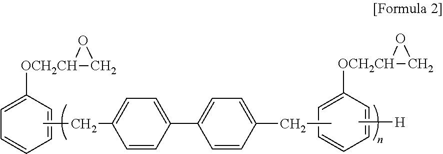

wherein n is an integer from 1 to about 7.

The curing agent may include about 10 to about 90 wt % of a phenol resin represented by Formula 4, below, based on a total amount of the curing agent:

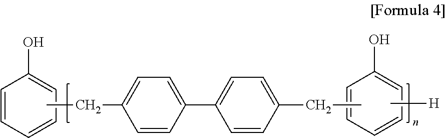

wherein n is an integer from 1 to about 7.

The embodiments may also be realized by providing a method of encapsulating a semiconductor device, the method including encapsulating a semiconductor device having a lead frame using the epoxy resin composition according to an embodiment; and curing the composition.

The embodiments may also be realized by providing a semiconductor device encapsulated with an encapsulant prepared from the epoxy resin composition according to an embodiment.

### DETAILED DESCRIPTION

Korean Patent Application No. 10-2010-0138323, filed on Dec. 29, 2010, in the Korean Intellectual Property Office, and entitled: “Epoxy Resin Composition For Encapsulating Semiconductor Device and Semiconductor Device Using the Same,” is incorporated by reference herein in its entirety.

Example embodiments will now be described more fully hereinafter; however, they may be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer or element is referred to as being “on” another element, it can be directly on the other element, or intervening elements may also be present.

An epoxy resin composition for encapsulating a semiconductor device according to an embodiment may include an epoxy resin, a curing agent, a curing accelerator, inorganic filler, and a flame retardant, which may include, or may be, boehmite.

Epoxy Resin

The epoxy resin may include an epoxy resin suitable for semiconductor encapsulation. For example, an epoxy compound containing at least two epoxy groups may be used. Examples of the epoxy resin may include epoxy resins obtained by epoxidation of a condensation product of phenol or alkyl phenol with hydroxybenzaldehyde, phenol novolac type epoxy resins, ortho-cresol novolac type epoxy resins, biphenyl type epoxy resins, multifunctional epoxy resins, naphthol novolac type epoxy resins, novolac type epoxy resins of bisphenol-A/bisphenol-F/bisphenol-AD, glycidyl ether of bisphenol-A/bisphenol-F/bisphenol-AD, bishydroxybiphenyl epoxy resins, dicyclopentadiene epoxy resins, and the like.

In an implementation, the epoxy resin may include a phenol aralkyl type epoxy resin of a novolac structure containing a biphenyl derivative as represented by Formula 2, below.

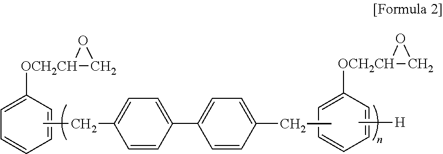

In Formula 2, n may be an integer from 1 to about 7.

The phenol aralkyl type epoxy resin represented by Formula 2 has a structure including a phenolic backbone and biphenyl at a middle of the structure. Accordingly, the epoxy resin may exhibit excellent hygroscopic resistance, toughness, oxidation resistance, and crack resistance as well as a low crosslinking density. Thus, a desirable level of flame retardancy through formation of a carbon layer (char) when burned at high temperature may be secured. The phenol aralkyl epoxy resin may be present in an amount of about 10 to about 90 wt %, based on a total amount of epoxy resin. Within this range, e.g., excellent balance of flame retardancy and fluidity may be obtained and molding defects may be reduced or prevented in a low-pressure transfer molding process for encapsulating a semiconductor device. In an implementation, the phenol aralkyl epoxy resin may be present in an amount of about 12 to about 85 wt %, e.g., about 15 to about 80 wt %, based on the total amount of epoxy resin. In another implementation, the phenol aralkyl epoxy resin may be present in an amount of about 15 to about 45 wt %, e.g., about 20 to about 40 wt %, based on the total amount of epoxy resin.

In an implementation, the epoxy resin may be a mixture of the epoxy resin represented by Formula 2 and at least one of ortho-cresol novolac type epoxy resins, biphenyl type epoxy resins, bisphenol-F type epoxy resins, bisphenol-A type epoxy resins, and dicyclopentadiene epoxy resins.

The epoxy resin represented by Formula 2 may be used in combination with a biphenyl type epoxy resin represented by Formula 3, below.

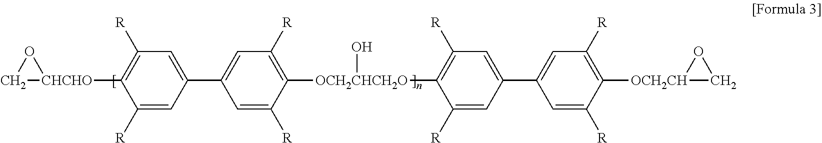

In Formula 3, each R may be a C1 to C4 alkyl group and n may be an integer from 0 to about 7. In an implementation, each R may be a methyl group or an ethyl group, e.g., a methyl group. The biphenyl type epoxy resin represented by Formula 3 may help improve fluidity and reliability of the resin composition.

A weight ratio of the epoxy resin represented by Formula 2 to the biphenyl type epoxy resin represented by Formula 3 may be about 1:1.1 to about 1:8.5, e.g., about 1:1.5 to about 1:6. Within the range, excellent moldability and reliability may be obtained.

The epoxy resins may be used alone or in combinations thereof. Further, there may also be used adducts, e.g., a melt masterbatch (MMB), obtained by reaction of these epoxy resins with other components, e.g., a curing agent, a curing accelerator, a release agent, a coupling agent, a stress-relief agent, and the like. Epoxy resins including fewer chloride ions, sodium ions, and/or ionic impurities may be used in order to help improve moisture and corrosion resistance.

The epoxy resin may be present in the epoxy resin composition in an amount of about 2 to about 15 wt %, e.g., about 2.5 to about 12 wt % or about 3 to about 10 wt %, based on a total amount of the epoxy resin composition.

Curing Agent

The curing agent may include a curing agent suitably used for semiconductor encapsulation. In an implementation, the curing agent may include at least two reactive groups.

Examples of the curing agent may include, but are not limited to, phenol aralkyl type phenol resins, phenol novolac type phenol resins, xylok type phenol resins, cresol novolac type phenol resins, naphthol type phenol resins, terpene type phenol resins, multifunctional phenol resins, dicyclopentadiene phenol resins, novolac type phenol resins synthesized from bisphenol-A and resol, polyhydric phenolic compounds, e.g., tris(hydroxyphenyl)methane, dihydroxybiphenyl, acid anhydrides, e.g., maleic anhydride and phthalic anhydride, and aromatic amines, e.g., meta-phenylenediamine, diaminodiphenylmethane, and diaminodiphenylsulfone.

The curing agent may include a phenol aralkyl type phenol resin of a novolac structure containing biphenyl derivatives and represented by Formula 4, below.

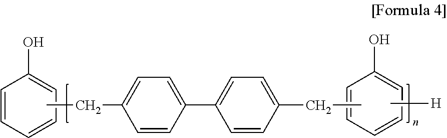

In Formula 4, n may be an integer from 1 to about 7. The phenol aralkyl type phenol resin represented by Formula 4 may react with the phenol aralkyl type epoxy resin represented by Formula 2 to form a char layer. The char layer may block transmission of ambient heat and oxygen, thereby helping realize flame retardancy.

The phenol resin represented by Formula 4 may be present in an amount of about 10 to about 90 wt %, based on a total amount of the curing agent. Within this range, excellent flame retardancy may be obtained without compromising fluidity. In an implementation, the amount may be about 12 to about 85 wt %, e.g., about 15 to about 80 wt %, based on the total amount of curing agent. In another implementation, the amount may be about 15 to about 45 wt %, e.g., about 15 to about 42 wt %, based on the total amount of curing agent.

The curing agent may include a mixture of the phenol resin represented by Formula 4 and at least one of phenol novolac resins, cresol novolac resins, xylok resins, and dicyclopentadiene resins.

The phenol resin represented by Formula 4 may be used in combination with a xylok type phenol resin represented by Formula 5, below.

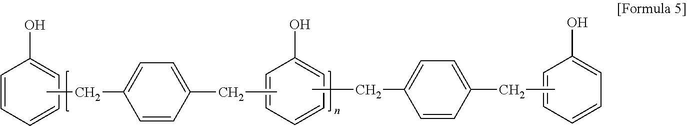

In Formula 5, n may be an integer from 0 to about 7. The xylok type phenol resin represented by Formula 5 may help improve fluidity and reliability of the resin composition.

A weight ratio of the phenol resin represented by Formula 4 to the xylok type phenol resin represented by Formula 5 may be about 1:1.1 to about 1:6.5, e.g., about 1:1.4 to about 1:6. Within the range, excellent moldability and reliability may be obtained.

The curing agents may be used alone or in combinations thereof. Further, there may also be used adducts, e.g., an MMB, obtained by reaction of these curing agents with other components, e.g., an epoxy resin, a curing accelerator, a release agent, a coupling agent, a stress-relieving agent, and the like.

The curing agent may be present in an amount of about 0.5 to about 12 wt %, e.g., about 1 to about 10 wt % or about 2 to about 8 wt % in the epoxy resin composition for encapsulating the semiconductor device. In an implementation, the curing agent may be present in an amount of about 2.5 to about 5.5 wt %.

Inorganic Filler

The inorganic filler may help improve mechanical properties of the epoxy resin composition and reduce stress. Examples of the inorganic filler may include, but are not limited to, fused silica, crystalline silica, calcium carbonate, magnesium carbonate, alumina, magnesia, clay, talc, calcium silicate, titanium oxide, antimony oxide, glass fiber, and the like.

Fused silica having a low coefficient of linear expansion may help reduce stress. Fused silica may refer to amorphous silica having a true specific gravity of about 2.3 or less, which may be prepared by melting crystalline silica or by synthesis from various raw materials. There is no particular restriction as to the shape and particle diameter of the fused silica. The fused or synthetic silica may have an average particle diameter of about 0.1 to about 35 μm. The inorganic filler may include about 40 to about 100 wt % (based on the total amount of the inorganic filler) of a fused silica mixture including about 50 to about 99 wt % of spherical fused silica (having an average particle diameter of about 5 to about 30 μm) and about 1 to about 50 wt % of spherical fused silica (having an average particle diameter of about 0.001 to about 1 μm). Within this range, excellent moldability may be obtained in a process of manufacturing a semiconductor device. The spherical fused silica may include conductive carbon on a surface thereof as an impurity. Thus, it may be desirable to use a spherical fused silica containing a smaller amount of polar impurities.

The amount of inorganic filler may be adjusted depending on desired properties, e.g., moldability, low-stress properties, and strength at high-temperature. In an implementation, the inorganic filler may be present in an amount of about 70 to about 95 wt %, e.g., about 75 to about 92 wt %, based on the total amount of epoxy resin composition for encapsulating the semiconductor device.

Flame Retardant

Boehmite is an inorganic flame retardant and may be represented by Formula 1, below.

AlO(OH) [Formula 1]

Boehmite exhibits excellent heat stability, dispersibility, and flame retardancy, has high purity, and is non-toxic (as compared with, e.g., alumina and aluminum hydroxide).

Accordingly, the composition according to an embodiment may include boehmite. The boehmite may begin to dehydrate at about 340° C. and may undergo mass loss of about 1% or less to about 400° C. Thus, excellent reliability may be exhibited due to high thermostability in molding, soldering, and substrate mounting processes of a semiconductor package.

In contrast, aluminum hydroxide may begin to dehydrate at a relatively low temperature, e.g., about 200 to about 230° C. In addition, about 10% of the mass may be drastically lost at about 300° C. A molding temperature of an epoxy resin composition used for encapsulating the semiconductor device may be about 160 to about 200° C.; and a temperature of soldering or substrate mounting processes may be about 240 to about 270° C. Thus, while an epoxy resin composition including aluminum hydroxide may exhibit flame retardancy, thermostability of a molded product may be reduced during molding, soldering, and substrate mounting processes of a semiconductor package. In addition, internal stress may increase due to generated moisture, thereby reducing product reliability.

The boehmite may have an average particle diameter of about 0.1 to about 10 μm. Within this range, excellent fluidity and reliability may be obtained. In an implementation, the average particle diameter may be about 1 to about 7 μM.

The boehmite may be present in an amount of about 0.1 to about 20 wt %, based on the total amount of epoxy resin composition. Within this range, excellent dispersibility, impact resistance, reliability, and moldability may be secured, and a desired degree of flame retardancy may be obtained.

A weight ratio of the boehmite to the inorganic filler, e.g., silica, may be about 1:3 to about 1:900. Within this range, good balance of flame retardancy and reliability may be obtained. In an implementation, the weight ratio may be about 1:5 to about 1:875, e.g., about 1:10 to about 1:870.

Curing Accelerator

The curing accelerator is a material that promotes a reaction between the epoxy resin and the curing agent. The curing accelerator may include, but is not limited to, tertiary amines, organometallic compounds, organic phosphorus compounds, imidazole compounds, boron compounds, or the like. Examples of the tertiary amines may include, but are not limited to, benzyldimethylamine, triethanolamine, triethylenediamine, diethylaminoethanol, tri(dimethylaminomethyl)phenol, 2-2-(dimethylaminomethyl)phenol, 2,4,6-tris(diaminomethyl)phenol, salts of tri-2-ethylhexanoic acid, and the like. Examples of the organometallic compounds may include, but are not limited to, chromium acetylacetonate, zinc acetylacetonate, nickel acetylacetonate, and the like. Examples of the organic phosphorus compounds may include, but are not limited to, tris(4-methoxy)phosphine, tetrabutylphosphonium bromide, tetraphenylphosphonium bromide, phenylphosphine, diphenylphosphine, triphenylphosphine, triphenylphosphine triphenylborane, triphenyl-phosphine-1,4-benzoquinone adducts, and the like. Examples of the imidazole compounds may include, but are not limited to, 2-methylimidazole, 2-phenylimidazole, 2-aminoimidazole, 2-methyl-1-vinylimidazole, 2-ethyl-4-methylimidazole, 2-heptadecylimidazole, and the like. Examples of the boron compounds may include, but are not limited to, tetraphenylphosphonium-tetraphenylborate, triphenylphosphine tetraphenylborate, tetraphenylboron salt, trifluoroborane-n-hexylamine, trifluoroborane monoethylamine, tetrafluoroborane triethylamine, tetrafluoroborane amine, and the like. In an implementation, the curing accelerator may include salts of 1,5-diazabicyclo[4.3.0]non-5-ene (DBN), 1,8-diazabicyclo[5.4.0]undec-7-ene (DBU), and phenol novolac resin salts. Organic phosphorus, amine, or imidazole curing accelerators may be used alone or in combinations thereof. The curing accelerator may also include adducts obtained from a reaction with the epoxy resin or curing agent.

The curing accelerator may be present in an amount of about 0.01 to about 2 wt %, e.g., about 0.02 to about 1.5 wt % or about 0.05 to about 1 wt %, based on the total weight of the epoxy resin composition.

Silane Coupling Agent

The epoxy resin composition for encapsulating the semiconductor device may further include a coupling agent. The coupling agent may be a silane coupling agent. The silane coupling agent is not specifically limited and may include compounds that react with the epoxy resin and the inorganic filler to improve interfacial strength between the epoxy resin and the inorganic filler. Examples of the silane coupling agent may include, but are not limited to, epoxy silane, aminosilane, ureido silane, mercapto silane, and the like, which may be used alone or in combinations thereof.

The coupling agent may be present in an amount of about 0.01 to about 5 wt %, e.g., about 0.05 to about 3 wt % or about 0.1 to about 2 wt %, based on the total weight of the epoxy resin composition.

The epoxy resin composition may further include an additive. Examples of the additive may include a release agent, such as higher fatty acids, higher fatty acid metal salts, and ester waxes; a colorant, such as carbon black, organic dyes, and inorganic dyes; and a stress-relieving agent, such as modified silicone oil, silicone powder, and silicone resins.

The release agent may be present in an amount of about 0.01 to about 7 wt %, e.g., about 0.05 to about 5 wt % or about 0.1 to about 3 wt %, based on the total amount of epoxy resin composition.

The colorant may be present in an amount of about 0.01 to about 7 wt %, e.g., about 0.05 to about 5 wt % or about 0.1 to about 3 wt %, based on the total amount of epoxy resin composition.

The modified silicone oil may be a silicone polymer having excellent heat resistance. For example, silicone oil having an epoxy functional group, silicone oil having an amine functional group, silicone oil having a carboxyl functional group, or a mixture thereof may be used in an amount of about 0.05 to about 2 wt %, based on the total weight of the epoxy resin composition. Within this range, surficial contamination may not occur, resin bleed may not be extended, and sufficiently low modulus may be obtained.

The epoxy resin composition may be prepared using the above components by the following general process. The components in a predetermined composition may be uniformly and thoroughly mixed using, e.g., a Henschel or Redige mixer. The mixture may be melt-kneaded in a roll mill or a kneader, cooled, and ground into a powdery product.

A method for encapsulating a semiconductor device using the epoxy resin composition may include encapsulating a semiconductor device having a lead frame using the epoxy resin composition, and curing the composition. In encapsulating the semiconductor device, low-pressure transfer molding, injection molding, and/or casting may be employed. According to this method, the epoxy resin composition may be attached to the lead frame, thereby manufacturing a semiconductor device having the encapsulated semiconductor device. The lead frame may include copper lead frames, e.g., a silver-plated copper lead frame, a nickel-alloyed lead frame, or the like.

For use, the lead frame may be plated with a material containing nickel and palladium, and then plated with at least one of silver and gold.

The following Examples and Comparative Examples are provided in order to set forth particular details of one or more embodiments. However, it will be understood that the embodiments are not limited to the particular details described. Further, the Comparative Examples are set forth to highlight certain characteristics of certain embodiments, and are not to be construed as either limiting the scope of the invention as exemplified in the Examples or as necessarily being outside the scope of the invention in every respect.

### EXAMPLES

Details of components used in Examples 1 to 6 and Comparative Examples 1 to 4 are as follows.

(A) Epoxy resin

(a1) Phenol aralkyl type epoxy resin: NC-3000, Nippon Kayaku

(a2) Biphenyl type epoxy resin: YX-4000H, Japan Epoxy Resin

(a3) Ortho-cresol novolac type epoxy resin: EOCN-1020-55, Nippon Kayaku

(B) Curing agent

(b1) Phenol aralkyl type phenol resin: HE200C-10, Airwater

(b2) Xylok type phenol resin: HE100C-10, Airwater

(C) Inorganic filler: Silica having an average particle diameter of 14 μm

(D) Boehmite: C-30, Taimei Chemical

(D′) Aluminum hydroxide: CL303, Sumitomo Chemical

(E) Curing accelerator: Triphenylphosphine, Hokko Chemical

(F) Silane coupling agent: γ-glycidoxypropyltrimethoxysilane (KMB-403, Shin Etsu Silicon)

### Examples 1 to 6

The components were prepared according to compositions listed in Table 1 and uniformly mixed using a Henschel mixer, thereby preparing a preliminary powdery product. The product was melt-kneaded at a maximum temperature of 110° C. using a twin screw kneader and then was cooled and ground, thereby producing epoxy resin compositions for encapsulating a semiconductor device.

Physical properties and reliability of the epoxy resin compositions were evaluated as follows. The test results of properties, flame retardancy, reliability, and moldability of each epoxy resin composition are given in Table 3.

### Comparative Examples 1 to 4

The same process as in Examples 1 to 6 was performed except that the components were mixed according to compositions listed in Table 2. The test results of properties, flame retardancy, reliability, and moldability of each epoxy resin composition are given in Table 4.

<Methods of Evaluation of Physical Properties>

1. Spiral Flow

A flow length (unit: inch) of each composition was measured using a measurement mold and a transfer molding press at 175° C. and 70 kgf/cm² according to EMMI-1-66. A higher value represents excellent fluidity.

2. Glass Transition Temperature (Tg)

Tg was measured using a thermal mechanical analyzer (TMA) while increasing the temperature at a rate of 5° C./min.

3. Electrical Conductivity (μs/cm)

A specimen of each cured epoxy resin composition was ground to a particle size of about 100 to 400 mesh using a grinder. 2 g±0.2 mg of the ground specimen was put in an extraction bottle and 80 cc of distilled water was added, followed by extraction in an oven at 100° C. for 24 hours. Then, electrical conductivity was measured using a supernatant of the extracted water.

4. Flexural Strength and Flexural Modulus (kgf/mm² at 25° C.)

A specimen (125×12.6×6.4 mm) was prepared according to ASTM D-790 and cured at 175° C. for 4 hours, after which flexural strength and flexural modulus were measured at 25° C. in 3-point bending using a universal testing machine (UTM).

5. Flame retardancy

Flame retardancy was evaluated using a specimen having a thickness of ⅛ inches according to the UL94 V-0 standard.

6. Moldability

Each epoxy resin composition in Table 1 or 2 was transfer molded at 175° C. for 120 seconds using a multi plunger system (MPS) with a mold press machine, thereby preparing an FBGA-type multi-chip package (MCP, 14×18×1.6 mm) in which four semiconductor chips were stacked up and down by an organic adhesive film. The package was subjected to post-mold curing (PMC) at 175° C. for 4 hours and cooled to room temperature. Then, voids observed on the surface of the package with the naked eye were counted.

7. Crack resistance (Reliability)

The package used in the moldability test was dried at 125° C. for 24 hours; and then subjected to 5 cycles of a thermal shock test (1 cycle refers to the package being left at −65° C. for 10 minutes, at 25° C. for 5 minutes, and at 150° C. for 10 minutes). Then, the package was subject to pre-conditioning, i.e., the package was left at 85° C. and a RH of 85% for 168 hours and then passed through IR reflow three times at 260° C. for 10 seconds. Using a non-destructive tester, e.g., a Scanning Acoustic Tomograph (SAT), occurrence of cracks was evaluated. Here, when a crack occurred, subsequent 1,000 cycles of the thermal shock test were not performed. When a crack did not occur after pre-conditioning, 1,000 cycles of the thermal shock test (1 cycle referring to the package being left at −65° C. for 10 minutes, at 25° C. for 5 minutes, and at 150° C. for 10 minutes) were performed using a Temperature Cycle Tester; and occurrence of cracks was evaluated using SAT. Semiconductor devices having at least one crack after pre-conditioning or the 1,000 cycles of the thermal shock test were counted; and results are shown in Tables 3 and 4.

TABLE 1

| Component | | | | | | | |
|---|---|---|---|---|---|---|---|
| (Unit: wt %) | | Example 1 | Example 2 | Example 3 | Example 4 | Example 5 | Example 6 |
| (A) | (a1) | 2.39 | 2.17 | 2.59 | 0.72 | 0.48 | 0.92 |
| (A) | (a2) | 3.59 | 3.26 | 3.89 | 4.08 | 2.65 | 5.24 |
| (B) | (b1) | 1.93 | 1.75 | 2.09 | 0.6 | 0.4 | 0.77 |
| (B) | (b2) | 2.89 | 2.62 | 3.13 | 3.40 | 2.27 | 4.37 |

| | | | | | | |
|---|---|---|---|---|---|---|
| (C) | 87 | 84 | 87 | 80 | 73 | 87 |
| (D) | 1 | 5 | 0.1 | 10 | 20 | 0.5 |
| (D') | — | — | — | — | — | — |
| (E) | 0.2 | 0.2 | 0.2 | 0.2 | 0.2 | 0.2 |
| (F) | 0.4 | 0.4 | 0.4 | 0.4 | 0.4 | 0.4 |
| Carbon black | 0.3 | 0.3 | 0.3 | 0.3 | 0.3 | 0.3 |
| Carnauba wax | 0.3 | 0.3 | 0.3 | 0.3 | 0.3 | 0.3 |

TABLE 2

| | | Com- | Com- | Com- | Com- |
|---|---|---|---|---|---|
| Component | | parative | parative | parative | parative |
| (Unit: wt %) | | Example 1 | Example 2 | Example 3 | Example 4 |
| (A) | (a1) | — | — | 0.65 | 0.54 |
| (A) | (a2) | 3.86 | 3.1 | 5.81 | 4.82 |
| (A) | (a3) | 1.74 | — | — | — |
| (B) | (b1) | — | — | — | — |
| (B) | (b2) | 4.91 | 2.7 | 5.34 | 4.44 |
| (C) | | 87 | 70 | 87 | 84 |
| (D) | | — | 23 | — | — |
| (D′) | | — | — | — | 5 |
| (E) | | 0.2 | 0.2 | 0.2 | 0.2 |
| (F) | | 0.4 | 0.4 | 0.4 | 0.4 |
| Flame | Bromated | 0.29 | — | — | — |
| retardant | epoxy resin | | | | |
| | Antimony | 1 | — | — | — |
| | trioxide | | | | |

| | | | | |
|---|---|---|---|---|
| Carbon black | 0.3 | 0.3 | 0.3 | 0.3 |
| Carnauba wax | 0.3 | 0.3 | 0.3 | 0.3 |

TABLE 3

| Categories | | Example 1 | Example 2 | Example 3 | Example 4 | Example 5 | Example 6 |
|---|---|---|---|---|---|---|---|
| Spiral flow (inch) | | 48 | 43 | 51 | 43 | 39 | 53 |
| Tg (° C.) | | 118 | 115 | 120 | 113 | 110 | 115 |
| Electrical conductivity (μs/cm) | | 15 | 17 | 12 | 18 | 21 | 12 |
| Flexural strength (kgf/mm²) | | 16 | 14 | 17 | 13 | 12 | 17 |
| Flexural modulus (kgf/mm²) | | 2429 | 2332 | 2445 | 2294 | 2112 | 2455 |
| Flame | UL 94 V-0 | V-0 | V-0 | V-0 | V-0 | V-0 | V-0 |
| retardancy | | | | | | | |
| Moldability | Number of | 0 | 0 | 0 | 0 | 1 | 0 |
| | voids (Visual | | | | | | |
| | Inspection) | | | | | | |
| | Total number | 3000 | 3000 | 3000 | 3000 | 3000 | 3000 |
| | of tested | | | | | | |
| | semiconductor | | | | | | |
| | devices | | | | | | |
| Reliability | Crack resistance | 0 | 0 | 0 | 0 | 0 | 0 |
| | (Thermal shock | | | | | | |
| | test) | | | | | | |
| | Number of cracks | | | | | | |
| | Total number | 3000 | 3000 | 3000 | 3000 | 3000 | 3000 |
| | of tested | | | | | | |
| | semiconductor | | | | | | |
| | devices | | | | | | |

TABLE 4

| | | Comparative | Comparative | Comparative | Comparative |
|---|---|---|---|---|---|
| Categories | | Example 1 | Example 2 | Example 3 | Example 4 |
| Spiral flow (inch) | | 48 | 36 | 54 | 41 |
| Tg (° C.) | | 121 | 109 | 114 | 112 |
| Electrical conductivity (μs/cm) | | 14 | 22 | 11 | 18 |
| Flexural strength (kgf/mm²) | | 17 | 10 | 16 | 14 |
| Flexural modulus (kgf/mm²) | | 2433 | 1965 | 2434 | 2297 |
| Flame | UL 94 V-0 | V-0 | V-0 | V-1 | V-0 |
| retardancy | | | | | |
| Moldability | Number of | 0 | 38 | 0 | 1 |
| | voids | | | | |
| | (Visual | | | | |
| | Inspection) | | | | |
| | Total number of | 3000 | 3000 | 3000 | 3000 |
| | tested | | | | |
| | semiconductor | | | | |
| | devices | | | | |
| Reliability | Crack resistance | 1 | 3 | 0 | 2 |
| | (Thermal shock | | | | |
| | test) | | | | |
| | Number of | | | | |
| | cracks | | | | |
| | Total number of | 3000 | 3000 | 3000 | 3000 |
| | tested | | | | |
| | semiconductor | | | | |
| | devices | | | | |

As may be seen in Tables 3 and 4, the epoxy resin compositions according to Examples 1 to 6 satisfied the UL94 V-0 flammability standard and also exhibited excellent moldability and reliability, as compared with the epoxy resin compositions according to Comparative Examples 1 to 4.

By way of summation and review, one way to impart flame retardancy to an epoxy resin composition for encapsulating a semiconductor device is to include a halogen flame retardant, e.g., bromine epoxy, or an antimony trioxide (Sb₂O₃) flame retardant. However, the epoxy resin composition using the halogen flame retardant, e.g., bromine epoxy, or antimony trioxide may generate toxic carcinogens, (e.g., dioxin or difuran) when combusted. In addition, the halogen flame retardant may generate gases, e.g., HBr and/or HCl, which are harmful to humans and may cause corrosion of a semiconductor chip or wire and a lead frame. Accordingly, flame retardants including phosphorus flame retardants, e.g., phosphazene and/or phosphate ester, and nitrogen atom containing resins, have been considered. However, phosphorus flame retardants may react with water, thus forming phosphoric acid and polyphosphoric acid, which may deteriorate reliability of a semiconductor device. In addition, nitrogen containing resins may exhibit insufficient flame retardancy.

Furthermore, imparting flame retardancy by increasing a content of an inorganic filler, e.g., silica, has been considered. However, although such methods may ensure flame retardancy and reliability, the inorganic filler may cause a drastic decrease in fluidity, dispersibility, and reactivity, thereby deteriorating moldability and processability.

The embodiments provide an epoxy resin composition for encapsulating a semiconductor device having excellent flame retardancy.

The embodiments provide an epoxy resin composition for encapsulating a semiconductor device including boehmite as a non-halogen flame retardant to provide excellent heat stability, reliability, and flame retardancy.

Example embodiments have been disclosed herein, and although specific terms are employed, they are used and are to be interpreted in a generic and descriptive sense only and not for purpose of limitation. Accordingly, it will be understood by those of skill in the art that various changes in form and details may be made without departing from the spirit and scope of the present invention as set forth in the following claims.

What is claimed is:

1. An epoxy resin composition for encapsulating a semiconductor device, the composition comprising:
an epoxy resin;
a curing agent;
a curing accelerator;
an inorganic filler; and
a flame retardant, wherein the flame retardant:
includes boehmite, and
is present in an amount of about 0.1 to 20% by weight (wt %), based on a total weight of the epoxy resin composition.

2. The epoxy resin composition as claimed in claim 1, wherein the boehmite has an average particle diameter of about 0.1 to about 10 μm.

3. The epoxy resin composition as claimed in claim 2, wherein the boehmite has an average particle diameter of about 1 to about 7 μm.

4. The epoxy resin composition as claimed in claim 1, wherein the inorganic filler includes silica.

5. The epoxy resin composition as claimed in claim 4, wherein a weight ratio of the boehmite to the silica is about 1:3 to about 1:900.

6. The epoxy resin composition as claimed in claim 1, wherein the epoxy resin composition includes:
about 2 to about 15 wt % of the epoxy resin,
about 0.5 to about 12 wt % of the curing agent,
about 0.01 to about 2 wt % of the curing accelerator,
about 70 to about 95 wt % of the inorganic filler, and
about 0.1 to about 20 wt % of the boehmite.

7. The epoxy resin composition as claimed in claim 6, further comprising about 0.01 to about 5 wt % of a silane coupling agent.

8. The epoxy resin composition as claimed in claim 7, wherein the coupling agent includes at least one of epoxy silane, aminosilane, ureido silane, and mercapto silane.

9. The epoxy resin composition as claimed in claim 1, wherein the epoxy resin includes about 10 to about 90 wt % of an epoxy resin represented by Formula 2, below, based on a total amount of the epoxy resin, 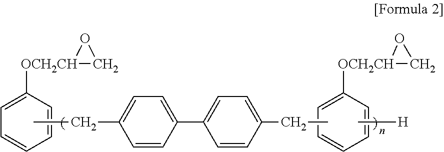
wherein n is an integer from 1 to about 7.

10. The epoxy resin composition as claimed in claim 1, wherein the curing agent includes about 10 to about 90 wt % of a phenol resin represented by Formula 4, below, based on a total amount of the curing agent: 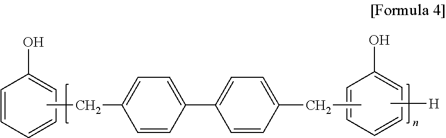
wherein n is an integer from 1 to about 7.

11. A method of encapsulating a semiconductor device, the method comprising:
encapsulating a semiconductor device having a lead frame using the epoxy resin composition as claimed in claim 1; and
curing the composition.

12. A semiconductor device encapsulated with an encapsulant prepared from the epoxy resin composition as claimed in claim 1.
